(19) United States
(12) Patent Application Publication
(10) Pub. No.: US 2010/0195841 A1
(43) Pub. Date: Aug. 5, 2010

(54) AUDIO EQUIPMENT

(76) Inventor: Fernando Eid Pires, Sao Paulo (BR)

Correspondence Address: CANTOR COLBURN, LLP, 20 Church Street, 22nd Floor, Hartford, CT, 06103, US

(21) Appl. No.: 12/679,702

(22) PCT Filed: Sep. 25, 2008
(86) PCT No.: PCT/BR2008/000290

§ 371 Date: Apr. 13, 2010

(30) Foreign Application Priority Data
Sep. 26, 2007 (BR) PI 0704910-2
Aug. 13, 2008 (BR) CI 0704910-2

(51) Int. Cl. H03G 3/00; H04B 1/20

(52) U.S. Cl. 381/61; 340/825.25; 381/119

(57) ABSTRACT

“AUDIO EQUIPMENT”, which includes a) Intuitive user interface for easy equipment operation; b) “Audio Link”, “P. A. Control”, “Programmable Stage Monitors”, “Output Terminal” and “Instrument Input Selector” features; c) Integrated sound effects and sound treatment functionalities; d) Conventional Equipments integration capability, which the user interface includes the front and back panel; the equipment in question includes regarding the Input Channels, the Microphone input channels with JlO non balanced and XLR balanced connection each, allowing both kinds of microphones to be connected simultaneously at in the same channel; the equipment includes et six Instrument input channels, with non balanced JlO connection, compatible with Active, Passive and Microphone instrument pick-ups, which the selection is made through a 3-position selector switch (9) at the back panel, with indication leds (2) for each chosen option; a programmable stage monitors system developed to allow the user to listen one or more desired instruments or microphones at the stage monitor loudspeaker, having yet an output terminal that uses a “DB-37” connector and a digital output interface; a vintage tone simulator; a selector for different instrument pickups, and yet, includes an Mp3 Player/Recorder.

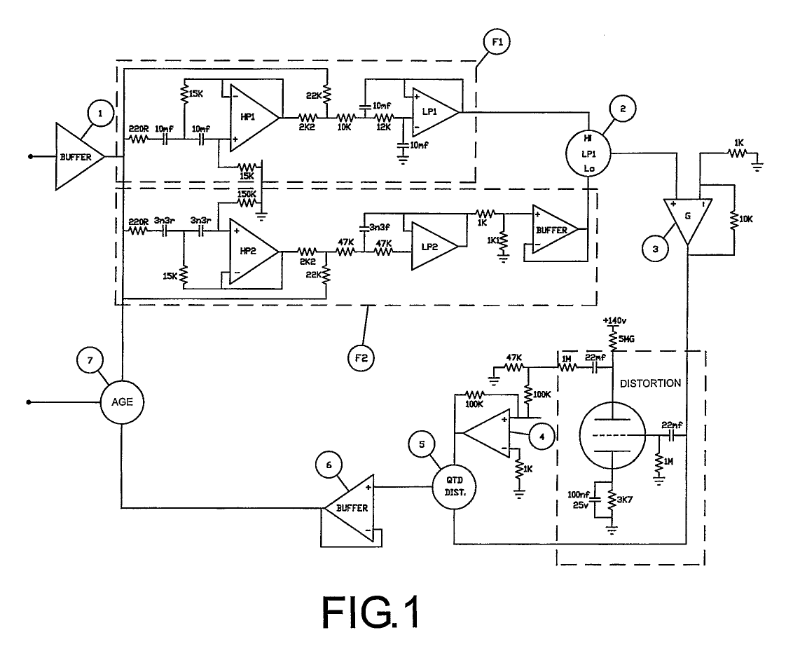

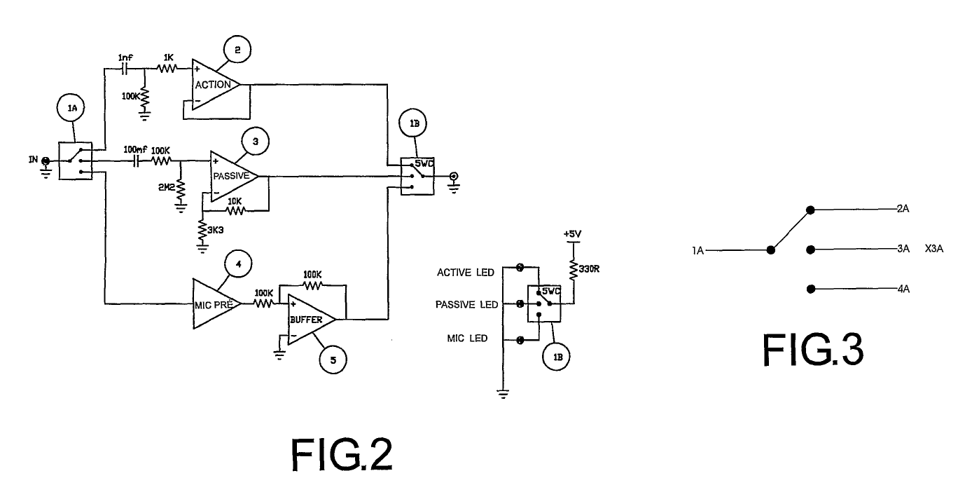

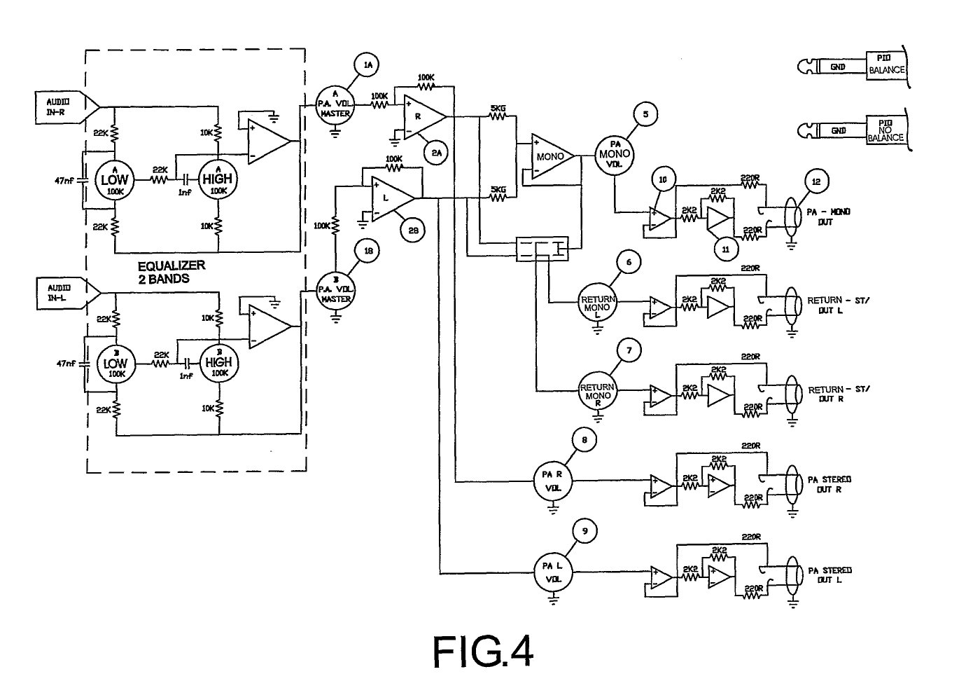

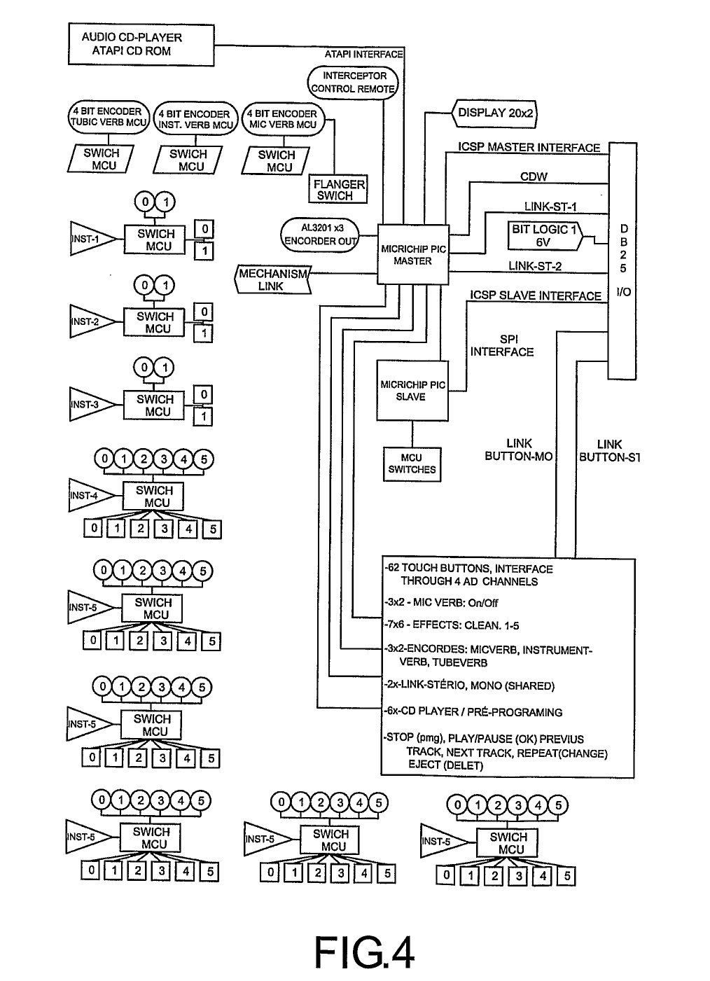

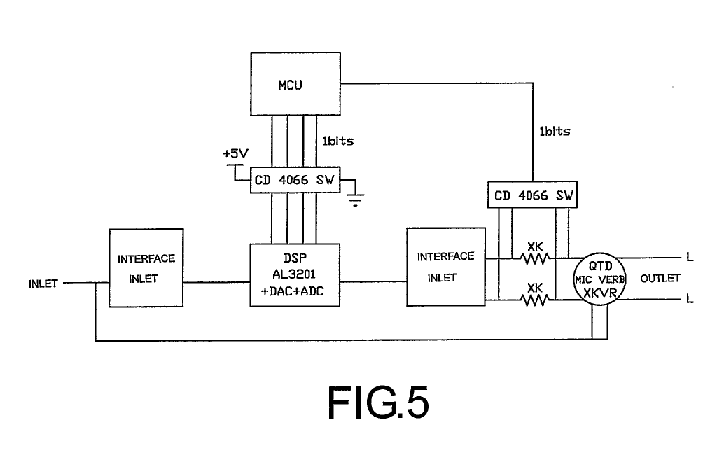

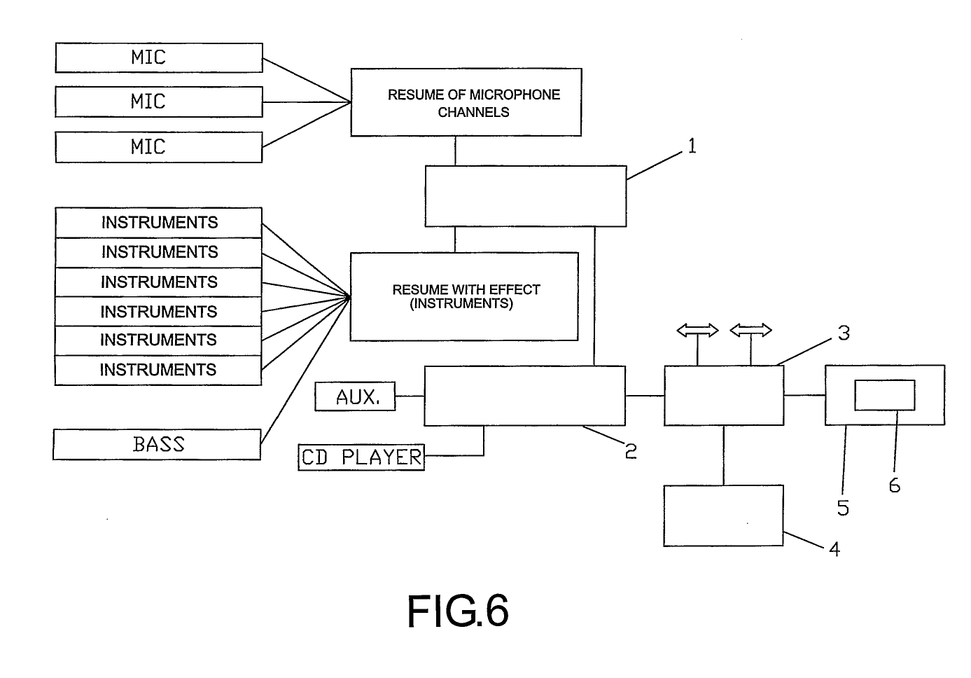

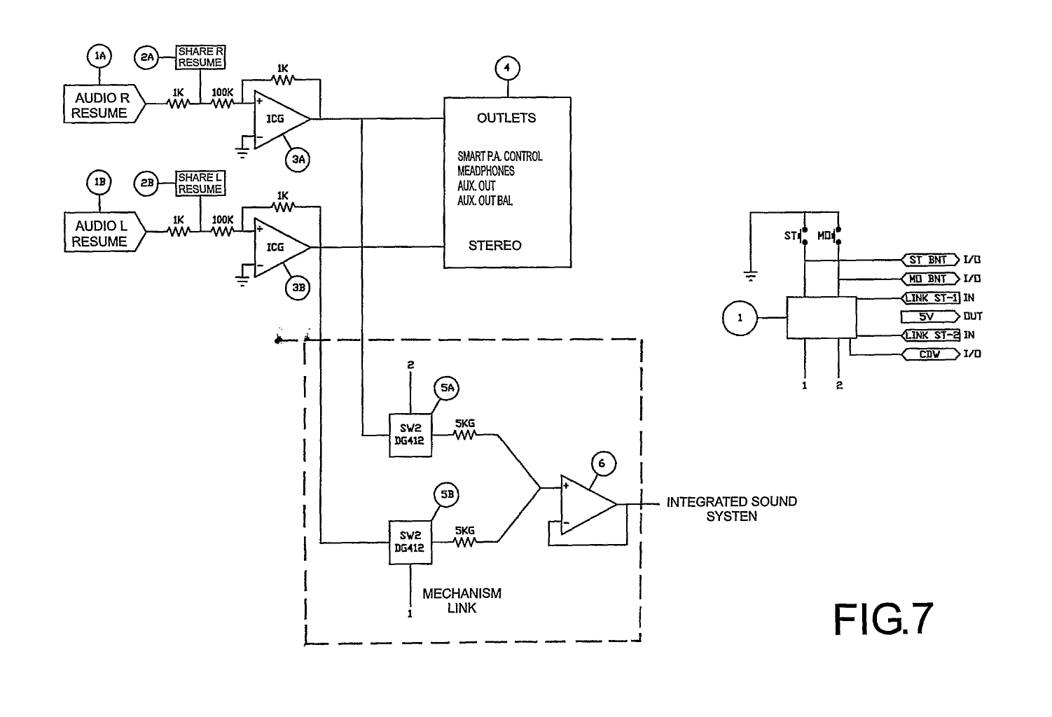

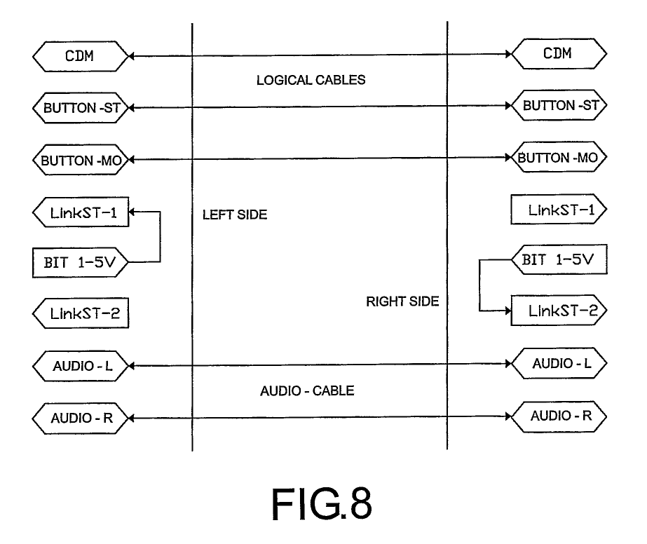

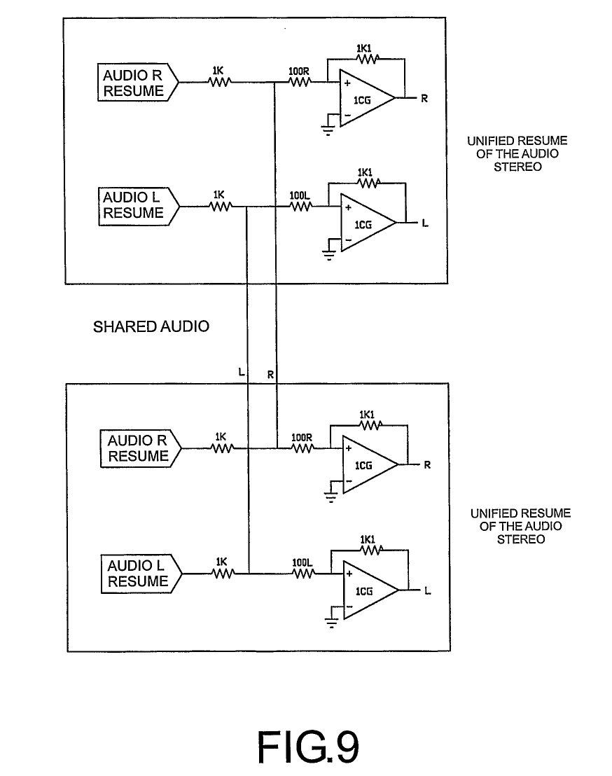

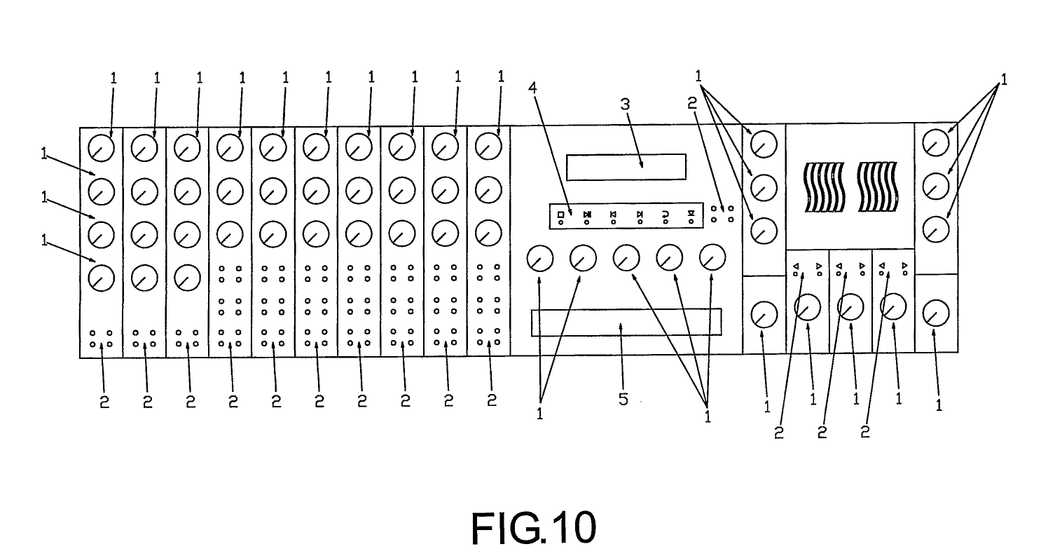

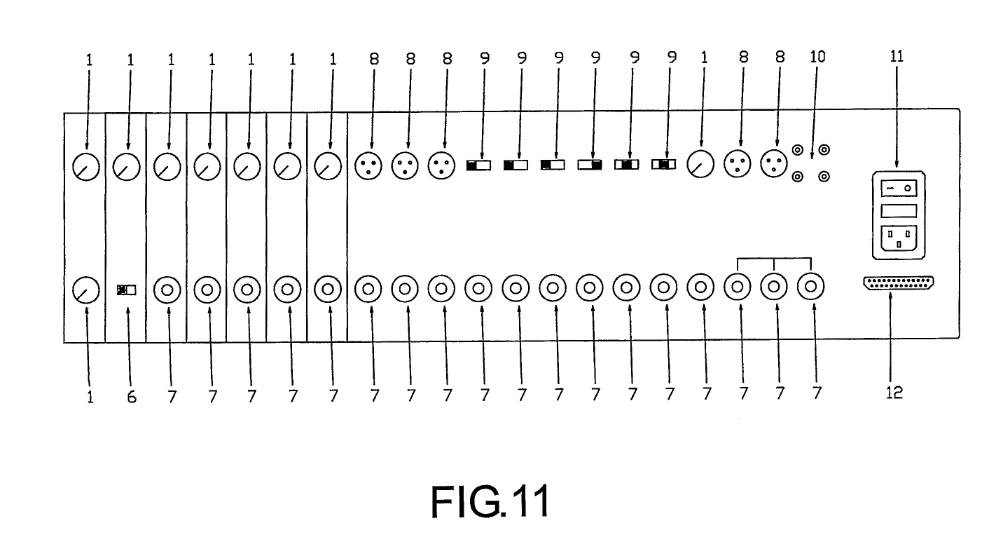

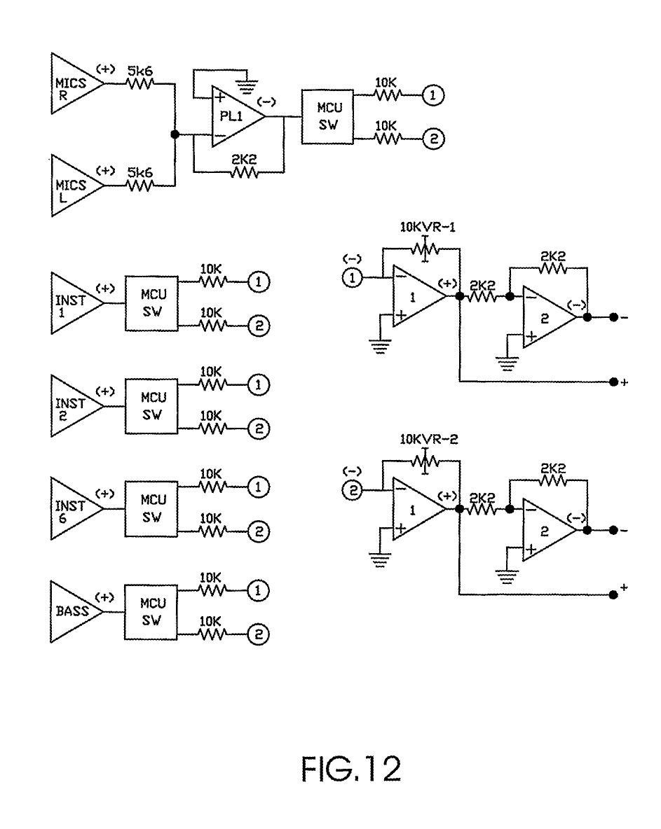

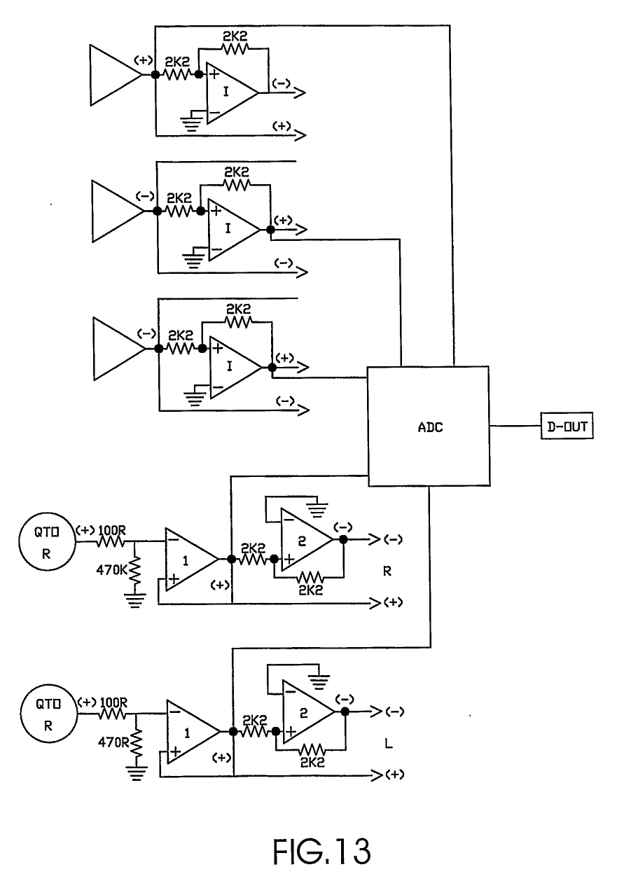

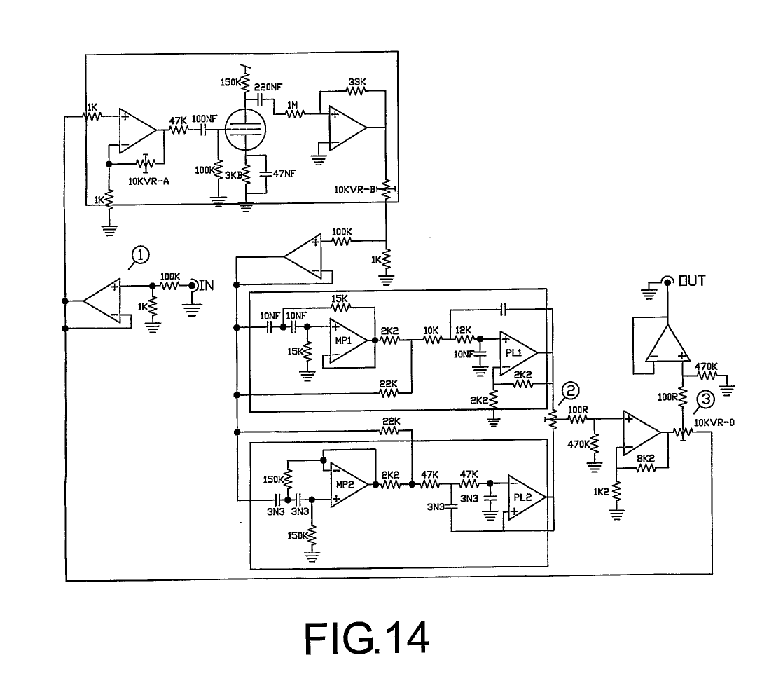

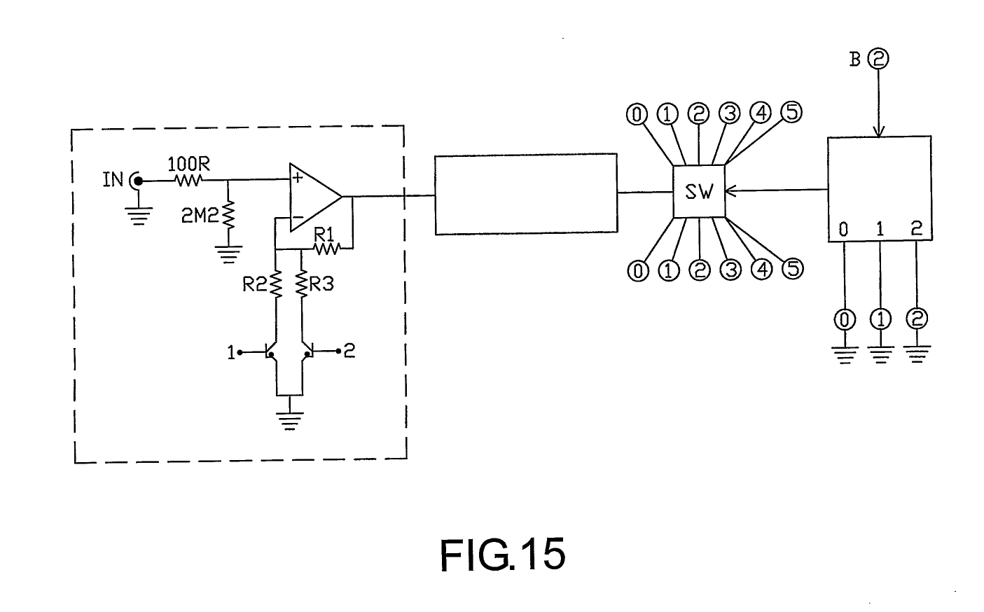

The present descriptive report is about an invention patent privilege, which proposes an audio equipment that is meant to be used as interface for many different kinds of instruments and other equipments such microphones.

The actual technical state determines that the equipments for musicians and musical bands forces the consumer to buy the basic, and after that, buy different items to join more functions to this basic kit that implies in more money spent and bigger number of different equipments.

Being this way, to obtain good features/functions, is necessary to buy many “modules” that are aggregated to the “basic kit” through many cables and connections, which causes many inconveniences during the operation and not practical situations, such unnecessary artist movement and usual problems of this kind of topology, such bad connections because of the wiring tangle to obtain these features. Furthermore, any medium or big size presentation needs a professional sound technician to manage the equipments, as the difficulty is present.

Also is important to mention, that in the actual scenery, equipments of different kinds can be aggregated, subjecting the whole set to different parts quality, interfering in its global performance, and making the user confused if the manufacturer needs to be contacted.

In face of this negative context from the Technical State, the equipment object of this invention patent privilege was developed, which creates a whole new concept regarding audio equipments, as it features new layout and interface, making a very robust and practical solution from amateur to professional utilization.

The present equipment offers the user, audio treatment features that only would be present in recording studios or in a huge set of pro-audio equipments. This new equipment offers the user all these features in a friendly way, through a very compact, and easy to transport package.

The present equipment is extremely useful in different situations, reaching this way, a wide range of public, as it is a flexible and high-quality solution. Easy utilization and transport, quality increase, optimization of the Cost vs. Benefit relation, are the main focus of this new solution. In order to complete the present project, many technical and creative solutions were designed, which will be all understood through the present report.

The equipment introduced here, comes from observation, opinion research, and technical solutions that allows a compact project, very easy to use, with both basic and advanced audio treatment features with excellent Cost vs. Benefit relation.

Inside the described above, the equipment shown here, fills the following objectives: a) create an intuitive interface for easy equipment use; b) be flexible, through the functions Link, Programmable Stage Monitors, Output Terminal, P.A. Control and Input Channel Selector; c) Have quality, through the carefully designed Hardware and the lack of user's mistakes due to the easy interface; d) have wide range of sound treatment features and integrated sound effects; e) optimize the Cost vs. Benefit relation; f) Supply immediately the artist's needs by providing many input and output channels; g) Be portable, allows organization and decreases the stage's setup time, obtained by abruptly minimizing the interconnections used in conventional equipments with the same features and; h) Be able to integrate with conventional equipments, allowing easy system adaptation and flexibility increase.

The equipment described here can be better understood through the detailed description from the observation of the related images bellow, which:
The image 1 illustrates an electric schematic of the effect “Oldalizer” expected in the present equipment;
The image 2 illustrates an electric schematic regarding the operation of the Input Channel Selector for instruments;
The image 3 illustrates an electric schematic of the P.A. System Control expected in the present equipment;
The image 4 illustrates a whole vision of the microcontroller-managed system expected in the present equipment;
The image 5 shows a general diagram of the integrated audio effects DSPs;
The image 6 illustrates a general diagram of the equipment;
The image 7 illustrates a vision of the Audio Link diagram, which is complemented by the image 8 that shows a cable connection between two equipments inside the Audio Link proposal;
The image 9 illustrates an electronic schematic regarding the audio sharing;
The image 10 illustrates a Front Panel diagram of the present equipment;
The image 11 illustrates a Back Panel diagram of the present equipment;
The image 12 illustrates a diagram of the Programmable Monitors;
The image 13 illustrates a diagram of the Output Terminal;
The image 14 illustrates a diagram of Oldalizer Vintage Tone Simulator; and
The image 15 illustrates a diagram regarding the Input Channel Selector for instruments.

In accordance with the amount of information provided by the related images above, the equipment object of this invention patent privilege must be understood as a sophisticated equipment that includes several features and functions, which will be described individually.

The present equipment regarding input channels includes, three microphone inputs with non-balanced J-10 connection and XLR balanced connection each, allowing two microphones to be connected in the same channel.

The equipment yet includes six input channels for instruments, with non-balanced J-10 connection. Compatible with Active, Passive and Microphone instrument pick-ups, the selection is made by pushing a tact switch in the back panel, with indicating leds for each chosen option.

By definition, must be understood that Active pick-up instruments are those that already have a built-in pre-amplifier; the Passive pick-up instruments are those that doesn't have pre-amplifier, so the signal from the pick-up element is sent directly to the amplifier; and the Microphone pick-up ones are any kind of instrument that uses a microphone to capture its sound.

Yet regarding the input channels item, the present equipment also includes an input channel for BASS instrument that also utilizes the same input selector system (Active, Passive, Microphone); and a Stereo Input Auxiliary channel with Volume control, to connect any kind of equipments.

Another feature expected in this object of invention patent privilege is an Audio CD-Player that is integrated and reproduces any Audio CD, which can be activated manually or through an established Pre-Program Mode.

The Audio CD-Player above described, works together with Audio Link and P.A. control, also have independent volume control.

The integrated Audio CD-Player is another feature expected in the present equipment, and it's new regarding equipments that belong to the actual Technical State.

The Audio Link makes the interface between two identical samples of the present equipment, managed by the microcontroller. The Audio link doubles all the features of the equipment, making both equipments in the established connection works like one since they're connected, as the integration is complete.

The Audio Link function also allows two equipments to work in Stereo mode, with the integrated transducer.

The Pre-Program Mode is another feature shown in this present equipment, being exclusive regarding equipments that belong to the actual technical state.

The Pre-Program Mode was specially conceived to offer more convenience and easy operation, as with this feature the user can program the whole musical sequence and intervals of a presentation, in order to avoid the necessary movement to configure the equipment in the desired way for each song and/or interval.

The Pre-Program Mode memorizes before, chosen attributes for the CD-Player, each Microphone and Instrument input channel, then it plays the desired sequence through a user touch in the remote control for each step.

The Audio Effects are other features expected in this present equipment, and are basically divided in two groups: The independent and the Shared ones.

The independents are audio features that are present in individual modules for each channel, offering this way, a peculiar adjustment without any dependence.

The shared are those effects that are present in unitary mode, being connected to the channels chosen by the user, which leads the adjustment made in the effect to be shown in all channels connected to it.

Inside the Independent group, are expected the independents for microphone, including the “Compressor”, that compress the voice, which makes it normalize (with level adjustment); “Echo”, that repeats the obtained sounds (with mix and repeat controls); “HPF”—High Pass Filter cleaner, that filters out the very low and subsonic frequencies, which optimizes the compressor response and cleans the sound; and “Mic Verb On/Off” switch, that connects or not the respective microphone channel to the Shared “Mic Verb” effect module.

Inside the Shared group, for microphone is expected the “MicVerb”, which creates artificial reverberation environments and flanger, such “Mic Hall 1”, “Mic Hall 2”, “Mic Plate”, “Mic Room”, “Mic Flanger”. The selection control between the effects is given through the switches “Previous” and “Next”, also it has “mix” control.

The present equipment also features other kinds of effects, including the independents for instruments, which includes the “HPF”—High Pass Filter that filters the undesired low frequencies and also optimizes de Compressor response (with level adjustment); “Compressor” that compress the Instrument's sound, which makes it normalize.

Yet inside the Instrument Effects group, there are the Shared effects, which includes the “Overdrive”, that distort the sound through an electronic tube buffer (with level adjustment); “Oldalizer”, that is a Vintage Sound Simulator, which works using specific frequency filters together with Tube distortion, in order to re-create the sound of vintage amplifiers (with Tone, Distortion and Age controls); “OverVerb”, that distort the sound through a Tube buffer (with level control) plus the Tube Verb effect; “OldVerb”, that is a vintage tone simulator, plus the TubeVerb effect; “InstrumentVerb”, that create many effects such “Reverbs”, “Delays”, “Echo”, “Chorus”, “Auto-Wah” and “Rotary Speaker”; “TubeVerb”, that is exactly the same as InstrumentVerb, but it is dedicated to the Tube effects only.

The effects “InstrumentVerb” and “TubeVerb” have the following variables: “Hall 1”, “Hall 2”, “Room 1”, “Room 2”, “Room 3”, “Plate 1”, “Plate 2”, “Plate 3”, “Delay 1”, “Echo”, “Chorus”, “Chorus-Room”, “Auto-Wah”, “Flanger”, “Rotary Speaker”.

The proposed equipment also have different output channels, three channels are for Stereo Head-Phones of any power or impedance; two are for auxiliary output, one is the usual RCA un-balanced to interface with any kind of equipment, and other is balanced XLR to interface with professional and recording equipments.

Still in the output channels item, the equipment has an integrated Mono Transducer, which can reproduce with fidelity the results obtained from the equipment's hardware. It's composed with Hi-Fi and Pro drivers, Bi-amplified with internal frequency cuts.

It's also expected yet in the output channels item, the “P.A. Control”, since one of the projects goal is to control the P.A. System directly, and the Stage Monitors as well without any external equipment aggregated. All the needed controls are in the equipments back panel, as can be seen in the image 13, with all the outputs being balanced/non-balanced types, eliminating the need for an external mixer connection in many cases.

Particularly regarding the “Oldalizer” effect shown by image 1, it has the function as already informed to create the “vintage” sound character from the old amplifiers, this effect features three adjustments: “Tone” that adjusts from the low to high sound character; “Distortion”, that mixes the clean with the Tube distorted signal; and “Age”, that mixes the signal without effect with the signal passed through the Oldalizer. Proportionally, as much less Oldalizer, more “new” is the obtained sound, just like as much more Oldalizer, more “old” is the obtained sound as well.

Technically, the Oldalizer works from a low impedance audio source, buffer 1, the audio goes forward to two different frequency filters, indicated as F1 and F2, both working the same way, but with different frequency setups.

In the Filter F1, the audio pass through HP1 that is a High Pass Filter, cutting 12 Db/oct in 1061 Hz, after that, the original signal is smoothly added by the resistor 22K, and then the audio goes to LP1, that is a Low Pass Filter cutting 12 Db/oct in 1592 Hz. This filtering process simulates the vintage Hi timber, still in the mid human audible region.

The process repeats with F2, but with two different details: The first one is the different frequency setups for the filters, 321 hz and 1026 Hz, creating this way the Low sound character, and the second is regarding the sound attenuation provided by resistors 1k and 1k1, as it was necessary in the implementation. After the filters F1 and F2, the sound goes to a simple audio buffer to match the impedance in order to correctly drive the potentiometer.

After the filters 1 and 2, the audio goes to the item 2, in order to provide to the user, ability to choose between Low and Hi sound character, this way we have the potentiometer “Tone Lo/Hi”, indicated by the numerical reference.

After the “Tone” potentiometer, the audio goes to another buffer indicated by the numerical reference 3, to match gain and impedance. After this step, the audio goes to two different ways, “clean” and “distorted” patch.

To distort the sound, a 12AX7 electronic tube was used, under-supplied with a 5M6 resistor. This way the sound is distorted, as the tube can't amplify the sound in the stipulated gain, creating a normalized and smooth distortion. The tube buffer inverts the signal phase and it's incapable to drive something with low impedance like the potentiometer ahead, so this signal coming from the tube pass through the inverted buffer 4, in order to correct the phase and match the impedance.

After the distortion step, the audio enters the potentiometer “Distortion” indicated by the numerical reference 5, located between the clean and distorted signal patches, it allows the user to mix the signals from clean to totally distorted.

After the potentiometer “Distortion” 5, the audio passes through another buffer 6 to match the impedance, in order to go directly to the “Age” potentiometer, which is indicated by the numerical reference 7, that also receives the signal without effect.

The “Age” potentiometer 7, is the component that mixes the “Oldalizer” effect amount.

About the Instrument Input Channel Selector, the present equipment introduces this feature in order to allow the user to have total flexibility with the Instrument input channels of the project. With this feature, musical instruments of any kind can be freely connected to any input channel. There are three different kinds of pick-ups: “Actives”; are those that have built in pre-amplifier, low output impedance and high gain; “Passives”: are those that doesn't have pre-amplifier, so the signal from the pick-up element is sent directly to the amplifier. They are high impedance output and low gain; and Microphone: Are all kinds of instruments, which have its sound captured using a microphone.

The image 2 illustrates an electronic diagram of the Instrument Input Selector, which works in the following way: The audio signal coming from the instrument is connected to its adequate pre-amplifier through the manual switch (indicated by numerical reference 1). This way, the input impedances are changed when different pre-amplifiers are selected. If the instrument is “Active”, its audio signal passes through an Audio buffer (indicated by numerical reference 2), with decoupling and properly grounding to avoid undesired oscillation, and protects the input channel as well.

If the instrument is “Passive”, its signal passes through a block with a determinate gain in order to compensate its lower gain. This block has enough high input impedance to work with any passive element, also has properly decoupling and grounding.

If the instrument uses a “Microphone”, its signal passes through a non-balanced microphone amplifier (indicated by numerical reference 4), which inverts the signal phase, so the signal is then sent to the inverted audio buffer (indicated by numerical reference 5) to correct the phase.

To avoid unnecessary noise, only the pre-amplifier currently in use will be connected to the equipment's signal patch, which is selected by the part “B” of the manual switch, that works according to the part “A”.

With the proposal to make visualization easier and avoid user mistakes, the part “C” of the manual switch is connected to three leds of different colors, and each color represents the current switch position.

The image 2 is complemented with a little diagram (image 2A), where the three positions of the switch 1 are shown and indicated as “2A”, “2B” and “2C”, where “A” is connected to the input of one of the three pre-amplifiers; “B” is connected to the output of one of the three pre-amplifiers; and “C” lights up the correct led according to the current switch position.

The equipment described here also features a system to handle the “P.A. Control”, being a hi flexibility function, it was designed specifically to be integrated to the present equipment, in order to make a perfect interface between the equipment and the P.A. System, avoiding this way, the use of an external mixer.

As can be seen in the image 4, through the use of 3 pins J-10 connectors, each output can make interface with balanced or non-balanced input amplifiers, the user must select the right cable to buy, the “balanced” or “non-balanced”, in order to make the right interface.

The “balanced” cable, have in one tip, 3-pin P10 connector, and in the other tip, XLR 3-pin connector. The non-balanced cable, have in both tips 2-pin P-10 connector.

The “P.A. Control” system has: Master P.A. Volume: Controls the volume of all outputs; Equalizer—Bass: Bass equalizer for P.A.; Equalizer—Treble: Treble Equalizer for P.A.; Stereo P.A. Output, through two J-10 connectors, with independent volume control for Left and Right sides; Mono P.A. Output, through a J-10 Connector, with volume control; Stage Monitor Output (or other application) Stereo or Mono, through 2 J-10 connectors, with independent volume control for Left and Right sides. The selection between Mono/Stereo is through a 2-position manual switch.

As can be seen in the image 3, the whole audio of the present equipment (Stereo, L—R), passes through a two-band equalizer with Bass and Treble controls. The equalizer uses dual potentiometers, in order to equalize both channels (L and R) at the same time. This equalizer is wide used in audio industry, and it's called Baxandall filter, that inverts the audio signal phase.

After the equalizer, the audio passes through the potentiometer “Master P.A. Volume” (item indicated by the numerical reference 1), that will control the audio amplitude of every block ahead. After this potentiometer, the signal passes again through audio buffers to match the impedance and correct the phase. After this step, the audio passes through three different ways, being: “P.A. Mono” output; “P.A. Stereo” output; and output for “Stereo/Mono Stage Monitor”.

For the first way, the stereo signal becomes mono by joining both channel sides with 5k6 resistors. After that it passes through an audio buffer (indicated by the numerical reference 3), to match the impedance with the next potentiometer “P.A. Mono Vol” ahead, which will control the signal amplitude in the mono output. Then the audio goes to the output-conditioning block.

For the second way, each side of the Stereo channel goes to an independent potentiometer (“P.A. —R Vol” and “P.A. —L Vol”, items indicated by the numerical references 8 and 9), offering the user, the ability to control the Left and Right P.A. volume sides separately. Then the audio goes to the output-conditioning block.

For the Third way, we have a manual two-position double switch (indicated by the numerical reference 4). For the two contacts of one side, the Stereo channels arrive. For the two contacts of the other side, the mono channel arrives. This way is possible to make the selection between Stereo and Mono channels, both as low impedance source to drive the potentiometer correctly. After this selector switch “MO/ST” (indicated by the numerical reference 4), there are two potentiometers (“Stage Monitor Vol-L” and “Stage Monitor Vol-R” indicated by the images 6 and 7), to control the audio amplitude for each channel side, then the audio goes to the output-conditioning block.

The output conditioning block receives the audio signal through a non-inverted buffer (indicated by the numerical reference 10) (phase (+)), that goes to the tip pin of the J-10 connector (indicated by the numerical reference 12) through the decoupling resistor 220R, yet in this buffer's output, there's another inverted buffer (indicated by the numerical reference 11) (phase (−)), that goes to the middle pin of the J-10 connector, through another 220R resistor. This way, we have a completely balanced output, if we use 3-pins P-10 connector, as the positive (+) and negative (−) signal phases are present, plus the ground. If we use 2-pins P-10 connector, the negative (−) phase is grounded through the 220R resistor and only the positive (+) phase goes to the pin together with the ground, generating this way, an usual non-balanced output.

The “Audio Link” is another feature expected in the present equipment, being characterized to allow in a smart and micro-controller managed way, the integration between two samples of the same equipment, becoming a high power and flexible tool, which doubles all the features and functions, interacting to each other. The audio link have basically the following functions: Join the internal Stereo audio channels of both equipments; turn two mono transducers into a Stereo/Mono working one.

Joining the stereo channels of both equipments, all the features are doubled, being: Audio CD-Player, Instrument Input Channels, Microphone Input Channels, Auxiliary Inputs and Outputs; P.A. Control; Headphone Outputs; and all the Audio effects and audio treatment functions.

The CD-Player must have a specific management from the Microcontroller, as when operating in Link mode, two CD-Player units are present in the same audio patch, and they can't play at the same time, as there's no functional or logical reason for that.

In order to turn two separate Mono transducers into one Stereo/Mono, the following items are necessary: Location, to inform the equipment “where” it is located in the space, knowing this way which side of the stereo it is supposed to assume (task designated to the microcontroller); While working in stereo mode, reproduce the stereo channel side according to its location; If there's intervention from the microcontroller asking for Inverted Stereo, the current sides of the stereo that are being reproduced are swapped. While working in common Mono mode, the joined sound of both stereo sides must be reproduced in each integrated transducer.

The microcontroller is responsible for: Decide what is the equipment's location in the space; Avoid conflict between CD-Players; Make the user-interface; Recognize the Audio Link connection.

The microcontroller managed system can be better understood looking the image 4, where the illustration represents in logical form, the way that the microcontroller is connected to the project's internal system.

The microcontroller mainly have the following functions: Control the CD-Player, be the encoder of the digital effects “Instrument Verb”, “TubeVerb” and “MicVerb”; control the switching of Microphone and Instrument Input Channels; control and manage the Audio Link; memorize the Pre-Program Mode, and play it when the command from the remote control is received; Make the user interface through tact buttons, leds and Display.

Regarding the Audio CD-Player control, the microcontroller will control the drive through the ATAPI interface, wide used in the computers. Its proposal is to turn an ordinary computer CD-ROM drive in an Audio CD-Player with the most usual functions. There are six buttons to control it, being: “STOP”; “Play/Pause”; “Previous Track”; “Next Track”; “Repeat”; and “Eject”.

These buttons stays on the front panel, to be easily accessible to the user. The CD-Player can also be controlled through an established Pre-Program Mode.

During the Audio Link operation, before execute the CD-Player, the microcontroller will ask the other equipment connected in the Link (through the “CDW” connection), in order to know if the other CD-Player isn't playing already, if the answer is positive, the operation will be aborted. These rules are applied in both cases, if the user or a pre-program is trying to execute the CD-Player.

In the digital effects encoder function, the microcontroller is encoder of three similar DSPs. The chip is the same for all implementations, but the available effects between them are different. The modules “InstrumentVerb” and “TubeVerb” will have 15 different effects, while the “MicVerb” will have only 5, and a switch that when the fifth effect is selected, will be turned on, in order to change the effect level.

The image 5 illustrates an electronic diagram of the microcontroller being encoder of the DSPs.

The microcontroller was in charge of being encoder of the DSPs because of the following reasons: Personalization—The manufacturer can control directly which effects will be available, and how will be utilized; Interface, it will show on the display, what is the currently in use effect for each DSP, making user's life easier. Tact buttons (previous and next) will be used to control the effects; Integration, with the microcontroller being encoder of the DSPs, the pre-program have the ability to change the desired effect, according to a user established pre-program mode.

The audio effects are the listed bellow:

### InstrumentVerb:

| | | |
|---|---|---|
| 1- | 1001 | Inst. Hall 1 |
| 2- | 1101 | Inst. Hall 2 |
| 3- | 0101 | Inst. Room 1 |
| 4- | 0001 | Inst. Room 2 |
| 5- | 0000 | Inst. Room 3 |
| 6- | 0100 | Inst. Plate 1 |
| 7- | 0110 | Inst. Plate 2 |
| 8- | 0010 | Inst. Plate 3 |
| 9- | 1111 | Inst. Delay 1 |
| 10- | 1011 | Inst. Delay 2 |
| 11- | 0011 | Inst. Chorus |
| 12- | 1010 | Inst. Chorus Room |
| 13- | 1110 | Inst. Auto-Wah |
| 14- | 0111 | Inst. Flanger |
| 15- | 1000 | Inst. Rotary Speaker |

### Tube Verb:

| | | |
|---|---|---|
| 1- | 1001 | Tube. Hall 1 |
| 2- | 1101 | Tube. Hall 2 |
| 3- | 0101 | Tube. Room 1 |
| 4- | 0001 | Tube. Room 2 |
| 5- | 0000 | Tube. Room 3 |
| 6- | 0100 | Tube. Plate 1 |
| 7- | 0110 | Tube. Plate 2 |
| 8- | 0010 | Tube. Plate 3 |
| 9- | 1111 | Tube. Delay 1 |
| 10- | 1011 | Tube. Delay 2 |
| 11- | 0011 | Tube. Chorus |
| 12- | 1010 | Tube. Chorus Room |
| 13- | 1110 | Tube. Auto-Wah |
| 14- | 0111 | Tube. Flanger |
| 15- | 1000 | Tube. Rotary Speaker |

### Mic Verb

| | | |
|---|---|---|
| 1- | 1101-0 | Mic Hall1 |
| 2- | 1001-0 | Mic Hall2 |
| 3- | 0100-0 | Mic Plate |
| 4- | 0000-0 | Mic Room |
| 5- | 0111-1 | Mic Flanger |

As the display is 20×2, we can have:

### “MicX-InstXY-TubeWZ”—X is the MicVerb Effect (1˜5) and XY is the InstrumentVerb Effect (1˜15) and WZ is the TubeVerb Effect.

### EXAMPLE

### “StudioClass I Mic5-Inst15-Tube01”

The “StudioClass I” is the name of the equipment for example. The first line of the display will show all the system messages, and also the complete name of the effects while the user is browsing the effects. Let's suppose that the “next” button of “TubeVerb” is pushed twice:

### “Tube Hall 1

### Mic5-Inst15-Tube01”

### Tube Hall 2

### Mic5-Inst15-Tube02”

After four seconds, the Line 1 of the display goes back to the last message:

### “StudioClass I

### Mic5-Inst15-Tube02

This is the way that the display is arranged to show the information regarding the audio effects.

Regarding the internal equipment's switching system integration, the microcontroller controls directly the instrument and microphone switching input channels.

Using an electronic switch (DG412), the microcontroller can handle this.

The advantages are: There's no physical stress as it would have in an analog mechanical switch; the equipment is more pleasant to use; less switching noises; interacts with the Pre-Program Mode feature.

For the input channels, there's an indicating led for each switch position. According to this, the microphone channels have two leds, while the instrument ones have six. These leds stays on the front panel, together with the corresponding tact buttons. The leds are directly connected to the switches, this way, the change on the switch's state is shown by the corresponding led.

There's also one tact button corresponding for each switch position, so the microphone channels have two buttons, while the instrument ones have six.

The integration with the Audio Link, can be understood looking the images 7 and 8, that illustrates an electronic diagram and a matching one:

In the image 7, the item 1 shows the whole audio output of the present equipment, being Stereo. Attention for the fact that this is the audio coming from one equipment sample, that when operating in Link mode, it is joined to the whole audio output of the other equipment sample, through the shared audio I/O (indicated by numerical reference 2), that connects the equipments together, through the audio cables shown on image 8.

Since the moment that the Audio Link Cable is inserted, the channels that carries the audio sum of each equipment, are joined together. For example, if in the first sample we have a Saxophone connected, and in the second sample we have a Violin, if the equipments aren't in Link Mode, the outputs of the first sample will reproduce only the Saxophone, while the outputs of the second sample will reproduce only the Violin. Connecting the samples together with the Audio Link Cable both instruments will be reproduced in each sample's output, thanks to the joined internal audio channels. This way, the inputs and outputs are joined, doubling the capacity of only one sample alone.

Starting from this point, and knowing that each equipment have an independent integrated mono transducer, in order to put two samples to work in stereo mode, is necessary to divide the sides of the stereo channel between them. For example, the first sample plays the Left side, while the second sample plays the Right. This way, a Stereo transducer is made from two mono transducers. In order to work is necessary to choose which sample will play the Left and which will play the Right side.

To decide the equipment's location on the space, we start from the knowledge that equipment's can't “see” or “perceive” where they are placed, so this task is for the user. Using the Audio Link Cable, the user will choose the initial working position for the Stereo, as the cable have “Left” and “Right” written in each connector.

As we know that the user can accidentally connect the cable sides (regarding the stereo position) wrong, we also have the “Inverted Stereo Mode”. If the user connects the cable sides wrongly, pushing the “ST” button will swap the stereo sides to the correct position. The Left sample will be the Right and vice-versa.

Furthermore, the user can desire to use the equipments in mono mode, even in established link connection mode. For example, if the user wants to use the equipment as monitor, while it sends the stereo sound to the P.A. So, we have Mono mode over link—If the user presses “MO”, the equipments will work in Mono mode, yet over link. So each equipment will reproduce both Left and Right stereo sides joined together, composing two Mono transducers that reproduces exactly the same sounds.

During the Mono mode over link operation, if the user push “ST”, it will work in stereo mode again, with the last stereo side position restored.

The buttons “ST” and “MO” are connected directly to each other through the link cable, as it is illustrated in image 8. So, doesn't matter which sample the button is pressed, both will answer to the command. These buttons only works if the Link is established, otherwise they are kept inactive.

The present equipment has a CD-Player, so while operating in Link mode, two CD-Player are present into the same audio channel, so the microcontroller must: Avoid the CD-Player execution if other CD-Player is already being executed.

So, the microcontroller is responsible to manage the whole Audio Link process, recognizing the Link Connection, making the user interface through the tact buttons “ST” and “MO”, exhibiting messages on the Display. The microcontroller recognizes the Audio Link connection through the “Link-ST1” and “Link-ST2” inputs. If one of these inputs receives the bit 1 (5V), the active Link condition is established, if none of these two inputs receives the bit, the Inactive Link condition is established. If “Link ST-1” receives the Bit 1, the equipment will be self-denominated Left side on the Audio Link. If “Link ST-2” receives the Bit 1, the equipment will be self-denominated Right side on the Audio Link.

In order to perform the job, the cable ties the Bit-1 to Link-ST 1 on the Left side, and ties the Bit-1 to Link-ST 2 on the Right side, as can be seen on the image 8. This way, the microcontroller is able to know its initial position over the Stereo mode that can be further swapped as explained above.

Obviously, nothing would work if the microcontroller couldn't command the hardware to work in its desired way. For that, there's the Link Mechanism. Only two connections to the microcontroller are necessary, being “1” and “2”, shown on image 7.

If the Pin 1 of the Link Mechanism is activated, the Left side is reproduced through the integrated transducer.

If the Pin 2 of the Link Mechanism is activated, the Right side is reproduced through the integrated transducer.

If during the normal operation the button “ST” is pushed, if the pin 1 is activated (left side), the pin 2 (right side) must be activated instead and vice-versa, swapping the Stereo sides position.

If the button “MO” is pushed during the Stereo operation, both 1 and 2 pins must be activated, in order to join both sides of the shared Stereo, generating the shared mono signal this way.

If there's no active Link, (Link-ST1 and Link-ST2 off), the pins 1 and 2 must be activated, in order to join both sides of the non-shared Stereo, generating the non-shared mono signal this way.

Regarding the electronic block, in the image 7, the item 1 represents the whole audio produced by the present equipment. This audio passes through 1k resistors in order to be shareable, the other sample have exactly the same hardware, so when they are connected together, the audio is mixed through the 1k resistors, as exemplified by image 9.

This way, a “unified audio sum” is obtained, that means the sum of both equipments audio. So, when the link is established, both equipments will obtain the same result after the “ICG” block (item 3A).

When the audio link is established, sharing the audio through the 1K resistors, there's an attenuation (3 Db), which is compensated by the summing amplifier “ICG”, that increases the gain then the connection is present. The 100R resistor is for decoupling, avoiding dangerous cable oscillations to reach the system. The impedances are low, to avoid oscillations coming from the long cable 30.

After the item 3A, where there's the “unified audio sum”, the signal is directed to the outputs of the equipment, as shown in image 7.

Also after this point, the operational mode of the integrated transducer is selected.

If mono, both switches (item 5) closes, in order to join together both sides of stereo channel, generating the mono audio this way; If it's stereo, only one of the two switches must close, in order to reproduce the left (SW1, item 5B) or the right (SW2, item 5A) side.

After this switching step, which is managed by the microcontroller, the obtained audio goes to the output buffer (item 6) for impedance matching.

The Pre-Program Mode, that is a functionality present in the project, is useful during a presentation, to avoid unnecessary artist movement to adjust the equipment for each new song or interval. With the Pre-Program, it's possible to memorize before, the entire settings for microphone and instrument channels and configure the CD-Player to play a determinate CD Track as well for each song. It's also possible to program intervals, which will mute the instruments and can play an Audio CD optionally.

Before the explanations regarding the Pre-Program Mode operation, is necessary to observe and define some attributes:

Selector=Group of ON/OFF switches that composes it. The microphone channels have 2-way selectors, while the instrument channels have 6-way selectors. The switch is supplied from a source, which is the channel in question, and connects this source to different ways, directing the audio from the channel to different effect modules into the equipment's system. The selector is controlled by the microcontroller; Channels=reference valid only here, regarding the microphone and instrument input channels in a general form; Position 1=Is when the selectors are in the first position “0”, clean. This position connects the channels to the internal system without using an effect module; Initial Position=Means that all selectors are turned to the Position 1; Empty Position=Means that the selectors don't connect the channels to anything. This way, the channels are isolated from the system, being muted; Encoder=Is the connection between the microcontroller and the audio effects chip (DSP). The microcontroller send different bits to select the chip effects. So when appear “encoder position” during the text, it's regarding to determinate audio effect in the chip in question. There's three implementations of the same audio DSP: InstrumentVerb, TubeVerb, and MicVerb. So there are three encoders on the microcontroller, in order to control all three DSPs; Hold the button=Hold the tact button about two seconds; Push the button=Only push the button, without hold it.

The “Pre-Program Wizard” can be activated anytime during the equipments operation. As soon as it's activated, it must: Memorize all the conditions that the equipment was before the wizard, in order to restore it after the end of the wizard, to continue the normal operation; Put all the channels selectors in the Empty position; Put the three encoders in the first position; Verify if the CD-Player is being executed; If the CD is being played, end it and memorize the number of CD-Tracks; If there's no CD being played, verify if there's any CD inserted in the tray, if positive, ask the CD-Player how many tracks there's on the CD, and memorize it; If there's no CD inside, continue normally without the CD.

The “Pre-Program Wizard” regarding the Register: It's understood as a song that the artist will perform, with a personal effects sequence for each channel (selectors position), just like the encoders position as well, allowing the user to choose a CD-Track to be played together.

The “Pre-Program Wizard” regarding the Interval: It's understood as pause during the user's performance, which the instruments are muted (selectors in empty-position), with or without an Audio CD playing, if it's playing, it will play with the Repeat function on by default.

The “Pre-Program Wizard” regarding the Interface: The “Pre-Program Wizard” will share the CD-Player buttons, being: “STOP”=“PGM”; “PLAY”=“OK”; “Repeat”=“Change”; “Eject”=“Delete”.

The CD-Player buttons listed above, change its function when “STOP” is held, initializing the Wizard, since this point, the buttons have its functions changed, with the ones listed above.

So, as mentioned, when the “STOP” button is held (it will be called “PGM” during the text), it activates the “Wizard”, just like it will end, saving its configurations as well.

During the “Wizard” execution, push this button will create an interval, and push it again will save the interval and continue the registers recording, as it will be better explained during the text.

The button “OK” is the confirmation button that will save a register and go to the next one to be added, during the wizard, pushing it. It also will complete the registers inclusion when held. As soon as the registers inclusion is complete, the user will be able to browse them, as it will be better understood ahead.

The button “change” will be used, in order to give the user the ability to change the register settings during the wizard, pushing it. Also it will be used, if the user wish to change an established already saved pre-program setup, holding it during the normal equipments operation, opening the wizard again, in order to make the desired changes.

The “delete” button has the function to delete registers and intervals added through the wizard (pushing it), and exclude an already saved pre-program setup (holding it) that waits for utilization as well.

The browsing buttons are the tact switches Previous and Next of the CD-Player. The equipment in question is complemented with a given one-button remote control, in order to use the pre-program mode. It will active and continue the pre-program step by step until its end.

The Pre-Program mode regarding the Behavior: Always that there's a register to be added, the selectors must be put in empty-position, and the encoders in the first position, just like a form field that is cleaned in order to add new data; If there's an Audio-CD inside, the wizard offers the options “Don't Play” and “Play XY” to be memorized in the registers, together with the selectors and encoders positions. XY corresponds the number of CD Tracks going from the first until the last; If there's no Audio CD inside, the wizard only offers the option “Without CD”, that can be changed inserting a CD when it's shown. In this case, the message “Without CD” will not be displayed anymore, and it will be replaced by the messages described above, which corresponds to the CD presence.

If the user records the registers without the CD inserted, so using the given option “without CD” and after some registers ahead he inserts the CD, the wizard proceeds normally, showing the options “Don't Play” and “Play XY” in accordance to the inserted CD.

Regarding the utilization examples, we have: Example with Audio CD inserted: the user holds “PGM”, then the Wizard is opened,

### “PGM 01—Don't Play

### Mic1-Inst01-Tube01”

Then the user selects the effect modules for each channel, (defining this way the selectors position) and the encoders position,

### “Mic Hall 2

### Mic2-Inst01-Tube01”

“Inst. Chorus

### Mic2-Inst11-Tube01”

### “Tube Delay 2

### Mic2-Inst11-Tube10”

Then the user pushes the button “OK”,

### “PGM 01—Don't Play

### Mic2-Inst11-Tube10”

Then the user browses the CD Tracks, to choose one to play,

### “PGM 01—Track 07

### Mic2-Inst11-Tube10”

Then the user pushes the button “OK” and the wizard goes to the next,

### “PGM 02—Don't Play

### Mic1-Inst01-Tube01”

Then the user chooses again the audio effect modules for the channels and the encoders' positions,

### “Mic Flanger

### Mic5-Inst01-Tube01”

“Inst. Auto-Wah

### Mic5-Inst13-Tube01”

### “Tube Room 3

### Mic5-Inst13-Tube05”

Then the user pushes “OK”,

### “PGM 02—Don't Play

### Mic5-Inst13-Tube05”

Then he decides that in this register, he doesn't want a CD to play, so he doesn't browse the CD tracks, only pushes “OK” again,

### “PGM 03—Don't Play

### Mic1-Inst01-Tube01”

This way, the user goes saving all the desired registers (let's suppose that 12 registers were added), till he decides that he wants an interval, so he pushes the “PGM” button,

### “Interval—Don't Play

### Mic0-Inst00-Tube00”

So the user utilizes the browsing buttons to change the optional CD-Player message, being the only options “Don't Play” and “Play All”,

### “Interval-Play All

### Mic0-Inst00-Tube00”

Then the user pushes “PGM” again, to continue adding registers after the programmed interval,

### “PGM 13—Don't Play

### Mic1-Inst01-Tube01”

Then the user stops adding desired registers and holds “OK” to conclude the pre-program,

### “PGM 13—Don't Play

### Mic1-Inst01-Tube01”

As the pre-programming is already conclude, the user can browse the recorded registers and intervals, using Previous and Next buttons.

When browsing, the selectors must be set into the registers recorded positions, giving the ability to the user visualize what was defined to in input channels through the panel leds, just like the encoders position must be shown and real changed when browsing, in order to allow the user to test the registers settings. If there's anything wrong, the user must select the desired register or interval (visualizing it), and push the “change” button, example:

### “PGM 01—Track 07

### Mic2-Inst11-Tube10”

### Next,

### “PGM 02—Don't Play

### Mic5-Inst13-Tube05”

### Next,

### “PGM 03—Don't Play

### Mic1-Inst01-Tube01”

The user perceives that the third is not according to what he wants, so he pushes the “change” button:

### “PGM 03—Don't Play

### Mic1-Inst01-Tube01”

Then the user includes the new sequence of audio effects for each channel (selector positions) and the new encoders positions,

### “Mic Room

### Mic4-Inst01-Tube01”

“Inst. Rotary Spk

### Mic4-Inst15-Tube01”

### “Tube Plate 1

### Mic4-Inst15-Tube06”

And pushes the “OK” button,

### “PGM 3—Don't Play

### Mic4-Inst15-Tube06”

Then chooses a CD Track and pushes “OK”,

### “PGM 3—Track 15

### Mic4-Inst15-Tube06”

This way the user modified the register 3 successfully.

When modifying an interval, the only change allowed is the option to play or not the CD. The user should proceed the same way, pushing the “change” button, use the Next and Previous buttons to choose the new option, and then push “Ok” to finish. Example:

### “Interval-Play All

### Mic0-Inst00-Tube00”

Then the user decides that he doesn't want CD playing during the interval, selecting the new option:

### “Interval-Don't Play

### Mic0-Inst00-Tube00”

Push the button “OK”.

### “Interval-Don't Play

### Mic0-Inst00-Tube00”

And this way, the interval was successfully modified.

As it was already explained, when browsing the registers and intervals, is possible to delete a selected item. Example:

### “PGM 01—Track 07

### Mic2-Inst11-Tube10”

### Next,

### “PGM 02—Don't Play

### Mic5-Inst13-Tube05”

### Next,

### “PGM 03—Track 15

### Mic4-Inst15-Tube06”

So, the user decides to delete register 2, so he comes back to the second register in order to select it, and pushes the “Delete” button.

### “PGM 03—Track 15

### Mic4-Inst15-Tube06”

### Volta,

### “PGM 02—Don't Play

### Mic5-Inst13-Tube05”

“Delete” was pushed, so the second register was deleted, and then the third register replaces its place,

### “PGM 02—Track 15

### Mic4-Inst15-Tube06”

When “PGM” is held, the Wizard is finished with saved settings, and it will be awaiting the execution, which will be given from the remote control command.

Before executing the Pre-Program established, although it's already saved and ready to execute, the equipment will work normally, just like if there's nothing saved, only will show “PGM —” in the left side of the message displayed in the first line of the display, informing that there's a pre-program saved, waiting execution.

### “PGM — StudioClass I

### MicX-InstXY-TubeWZ”

The pre program can be deleted, holding the “delete” button, so “PGM —” disappears, and the pre-program is erased.

### “StudioClass I

### MicX-InstXY-TubeWZ”

The pre-program already saved can be edited pushing the “change” button, so the pre-program mode wizard will show up again and allow the user to browse the registers and intervals normally, as explained in the “changes” topic above. The user will be able to edit anything pushing the “change” button, and save the modification pushing the “Ok” button. To end the wizard, the user holds “PGM” as explained before.

The pre-program will be only executed if the equipment receives the signal coming from its remote control. With one touch, it executes the first register, and goes on as the user ask for touching the remote control, till the end. When finished it will come back to its awaiting state, and can be further executed if activated through the remote control again.

From the practical operation point of view, the equipment here can be better understood through the physical visualization, according to the images 10 and 11, that illustrates front an back panel diagrams respectively.

The image 10 that shows the equipment's front panel, and allow the visualization of how the many functions are organized, starting from the left to right, the potentiometers groups regards the microphones “MIC 1”, “MIC2” e “MIC 3”, according to the controls “Volume”, “Compressor”, “R. Echo” e “Echo Mix”, being together with indicating “On/Off” leds 2 for the “MicVerb” effect module.

After the potentiometers groups that refers to the microphones, are disposed the groups of potentiometers regarding the instruments, which are indicated as “Inst. 1” till “Inst. 6”, plus the Bass Instrument. These potentiometers are arranged in groups to control “Volume”, “HPF” e “Compressor” and are together with indicating leds 2 for the six available functions (clean, Oldalizer, Overdrive, OldVerb, OverVerb and InstrumentVerb).

After that, the equipment's front panel shows the display 3, which is complemented by the functional keys 4, being expected leds 2 indicatives for the “Audio Link” function, to visualize the Stereo L-R and Mono mode operation.

The front panel still includes in the same section, potentiometers 1 to control microphones, instruments, CD-Player, Head-Phones and Master, being yet visible the tray 5 where the Audio CD is inserted.

On the sequence, the front panel yet includes potentiometers 1 for the effect “Oldalizer”, regarding “Tone”, “Distortion” and “Age”, with another potentiometer for the “Overdrive”.

Are also expected, potentiometers and leds to control the effects “MicVerb”, “InstrumentVerb”; “TubeVerb”; “OldVerb” (with potentiometers to control “Tone”, “Distortion” and “Age”; and “OverVerb” with distortion level potentiometer.

The equipment's front panel yet includes as visual design, windows that allow the Tubes visualization, used to produce the Oldalizer and Overdrive effects.

The image 11 shows the equipment's back panel, which includes from the left to right, potentiometers related to the “P.A. Control” system that includes a potentiometer 1 for Bass control; a potentiometer for treble control; potentiometers to control left and right stage monitor sides volume, denominated “Stage Monitor—L” and “Stage Monitor—R”; other potentiometers 1 to control the functions “P.A. —L”, “P.A. —R” and other potentiometer for the “P.A. —Mo” function.

The same back panel section yet includes, related to the “P.A. Control” system, a potentiometer 1 that refers to “Master P.A. Vol”, a two positions switch to control the “Stereo/Mono” output for the stage monitors; just like output connectors for “RET-L”; “RET-R”; “P.A.-L”; “P.A.-R” e “P.A.”-Mo”.

The central back panel section includes connectors 8 for cables “XLR Bal.” For “Mic 1”, “Mic2” and “Mic3”, just like 3-position switches that refers to the kind of the instrument's pick-up, with Leds that refers to the “Active” “Passive” and “Microphone” pick-up kinds, represented by the numerical reference 9.

The back panel also includes a potentiometer 1 to control the “Aux.-In” function, and connectors 9 for the “Aux. —L”, “Aux. —R” and “Auxiliary L and R” functions indicated by the numerical reference 10.

The same back panel includes too, input connectors 7 for microphones indicated as “Mic. 1”, till “Mic. 3” (non-balanced), just like inputs 7 for instruments indicated as “Inst. 1” till “Inst. 6” plus “Bass Instrument”, and Head-Phones output.

Finally, the equipment's back panel also includes mains inlet and fuse 11, just like a DB-25 connector for the “Audio Link” function as well.

More over, the Programmable Monitors system applied in the audio equipment, was developed to allow the user to have the possibility of listening one or more desired instruments/microphones on the stage monitor loudspeaker, in a dynamic way. For example, a musician playing Bass instrument, many times needs to listen only the Bass sound on the loudspeaker, just like the singers must listen with more intensity only their voices.

Focused on the principal needs claimed by the artists, eight options were selected to be used by the Programmable Monitors function:

1° Microphones (all, with or without MicVerb);

### 2° Instrument Channel 1;

### 3° Instrument Channel 2;

### 4° Instrument Channel 3;

### 5° Instrument Channel 4;

### 6° Instrument Channel 5;

### 7° Instrument Channel 6; and

### 8° Bass Instrument Channel;

The available options can be freely selected for the target monitor, any option can be selected, as many as desired, and mix them in any way, allowing the user to find the best combination.

The selection is managed by the microcontroller, using tact buttons and display for user-interactive interface, verify ahead on the section “Switching Control—Programmable Stage Monitors”.

The electronic operation is given from the “Summing Amplifier” principle, that is an operational-amplifier configuration to accept multiple inputs, without having difference between them. This way, the channels can be connected an unconnected in any way, without restrictions.

The microphones channel output (with or without MicVerb effect) is found in Stereo Mode, and in non-inverted phase (+). In order to have compatibility with the programmable stage monitor system, it must be Mono and with inverted Phase (−). In order to adequate it, the resistors 5k6 that succeeds “Mics R” and “Mics L” turns the Stereo into Mono, then the signal goes to the Block 1, to invert the phase, being this way adequate to integrate with the system, through the electronic switches.

The Instrument/Bass Instrument Channels are already found exactly in the necessary form to integrate with the programmable stage monitors system, Mono, with inverted phase, so it goes directly to the electronic switches in question.

The electronic switches are controlled directly by the microcontroller, which makes the user-interface, allowing him to decide which channels he wants to connect to the target stage monitors.

When there's no connection to the Summing Amplifier (represented as “sum” on the diagram), there will be no audio or electric signal on the monitor's output.

When there's a connection, the phase will become non-inverted (+) again, generating the properly output signal for the Stage Monitor amplifier, right after becoming non-inverted, going out of the “Sum” block, it pass through the next block ahead to be inverted again, through the 2k2 resistors, generating this way the inverted phase output (−) to the stage monitor amplifier. This way, we have a totally balanced output (+) and (−), that depending of the connection method, can be used as balanced or standard non-balanced connection.

10KVR—1 Represents the Stage Monitor 1 volume control.
10KVR—2 Represents the Stage Monitor 2 volume control.

### Switching Control—Programmable Stage Monitors:

The microcontroller have the ability to control the “Programmable Stage monitors” switching. Its function is basically to replace the unpleasant mechanical noisy switches that compose a bad user-interface. Using Display and tact buttons, the user can select the desired options in a simple and interactive way.

The microcontroller have two “Wizards” in its internal software, to help the user to make the tasks in an easy way, they are: The Programmable Stage Monitors Wizard, and the Pre-Program Mode wizard.

Both Wizards share the Mp3-Player buttons, which change the function when activated in the described way:

### STOP=PGM

### PLAY/PAUSE=OK

### Previous Track=Previous

### Next Track=Next

### REPEAT=Change

### EJECT=Delete

To activate the wizard mode, PGM must be held about 2 seconds, then the “Wizard Selector” is opened:

### Monitor-Select? Pre-PGM?

### - - -OK- - -

Using the Previous and Next buttons, the “- - -OK- - -” cursor can be moved, in order to select which Wizard should be opened. In this case, we select “RTN-Select”, pushing “OK” button.

Then the Wizard will ask which one of the two available monitors output the user wish program:

### Monitor 1? Monitor 2?

### - - -OK- - -

So the user selects between Monitor 1 and Monitor 2, using Previous and Next buttons and pushing OK:

### Monitor 1:

[symbol] MICS

[symbol]

Oh the first Display line, “Monitor: 1” appears, and on its side, bars will appear in accordance to the chosen options, the maximum options are eight, being:

MICS

INST 1

INST 2

INST 3

INST 4

INST 5

INST 6

BASS

Are selected using Previous and Next button, and OK must be pushed to apply it, example:

The user wants to select the instrument channels 2, 4 and 5 to be reproduced on the Monitor 1:

### Monitor 1:

[symbol] MICS

[symbol]

### Next . . . .

### Monitor 1:

[symbol] INST 1

[symbol]

### Next . . . .

### Monitor 1:

[symbol] INST 2

[symbol]

OK is pushed . . . .

### Monitor 1: ▪

[symbol] INST 2

[symbol]

### Next . . . .

### Monitor 1: ▪

[symbol] INST 3

[symbol]

### Next . . . .

### Monitor 1: ▪

[symbol] INST 4

[symbol]

Ok is pushed . . . .

### Monitor 1: ▪ ▪

[symbol] INST 4

[symbol]

### Next . . . .

### Monitor 1: ▪ ▪

[symbol] INST 5

[symbol]

Ok is pushed . . . .

### Monitor 1: ▪ ▪ ▪

[symbol] INST 5

[symbol]

If some how the user program it wrong, Delete must be pushed, example:

### Monitor 1: ▪ ▪ ▪

[symbol] INST 5

[symbol]

Delete is pushed . . . .

### Monitor 1:

[symbol] INST 1

[symbol]

So he can select the channels to be reproduced on Monitor 1 again.

As soon as the Monitor is programmed as desired, PGM must be held, and then the Wizard ends with the settings saved.

If the user wishes to make the Monitor 2 program or a Pre-Program, Back must be held, and the Wizard will get back to the last screen, example:

The user is not satisfied with the Monitor 1 program, and wishes to come back to the last screen:

### Monitor 1: ▪ ▪ ▪

[symbol] INST 5

[symbol]

Back is held for 2 seconds . . . .

### Monitor 1? Monitor 2?

### - - -OK- - -

So in the screen shown above, he can program the Monitor 2, making the procedure already described, or hold the Back button again:

### Monitor-Select? Pre-PGM?

### - - -OK- - -

On the screen shown above, he can use the Pre-Program Wizard, or Hold PGM to end the Wizard selector, with the new settings saved.

### Output Terminal:

Researches about professional utilization, showed clearly that the present equipment would be much more useful if its internal channels could communicate with the world individually.

The equipment's output terminal was created to improve its flexibility and compatibility. With this, is easier to make interface with equipments from the old topology, making the migration an easier task, also is possible to make interface with huge pro audio mixers, needed in huge events, just like record each microphone, instrument and effect channels separately, into separate recording tracks when working in a recording studio.

This feature, allow make true professional recordings using the equipment, as recording the tracks without hardware effects makes the software adjustments unlimited.

Connect it to a bigger mixer, means that the artist will be free to make adjustments like Compression, Volume, Filters, Echo, without need the sound technician intervention.

In order to make it possible, the output terminal uses a DB-37 connector, which exposes all the balanced outputs to be connected to equipments with either balanced or non-balanced input connection.

The microphone, instrument channels, just like the effects Oldalizer and Overdrive, already have a buffer on its output, which allows a perfect impedance matching, so just another inverted audio buffer, identified with “I” is added, to invert the signal phase, generating a totally balanced output, with (+) and (−) phases to interface with pro audio equipments.

The audio of the effects MicVerb, InstrumentVerb and TubeVerb are recovered from the mixing potentiometers, so the impedance matching isn't correct, needing this way, another buffer (item 1) to match it, generating the phase (+), and another inverted buffer right after to invert the phase, generating the phase (−); This way we obtain the perfect impedances matching and a totally balanced output (+), (−) according to the adequate interface for the output terminal. Pay attention for the fact that the effects have Stereo Output, and both stereo sides are available at the output terminal.

At all, we have 36 pins used of the DB-37 connector. Each microphone channel uses two pins, just like the instrument, Oldalizer and Overdrive channels as well. The effects coming from the audio DSPs, MicVerb, InstrumentVerb and TubeVerb uses 4 pins for each, as the output is Stereo and balanced.

3×2=6 (microphones)

7×2=14 (instruments)

2×2=4 (Oldalizer and Overdrive)

3×4=12 (MicVerb, InstrumentVerb and TubeVerb)

The pin 37 and the body of the DB-37 connector are used as ground.

Also a digital output interface is used, which is obtained through the use of an internal ADC (Analog to Digital Converter) that allows the equipment to be connected to a Digital mixer, allowing the operation as a conventional “ADC”, but with its own control, treatment and sound effects features that are accessible to the artist on the stage.

### Oldalizer:

The already shown “Oldalizer” effect is described bellow in its new version, created from listening tests together with professional artists, in order to improve its fidelity and quality

The Oldalizer was developed to create the “vintage” sound from old amplifiers.

It has 3 controls:
Tone: Adjusts between the Lo and Hi sound character
QTD. Dist: Adjusts the Tube Buffer to obtain the desired distortion.
Idade: Mix the clean signal, with the Oldalizer output signal. More Oldalizer, more old sound, less Oldalizer, more new sound. Technically, the Oldalizer works in the following way:

From a low impedance audio source (buffer item 1), the audio goes to the first distortion block, where 10KVR-A (QTD Dist) multiplies the received audio signal from 1× to 10×, depending of the user's adjustment. The higher the multiplication, more over-fed is the Tube represented on the Diagram, generating this way the distortion. After going through the Tube, the second block of the distortion system recovers the audio, and then it is divided by 10KVR-B (QTD Dist) by the same factor as it was multiplied before. Then, if the audio was multiplied 1×, it will be divided by 1×. If it was multiplied by 7× it will be divided by 7×, keeping the same audio amplitude to be listened, showing this way only the selected distortion.

After going out of the distortion system, the audio is received by the block 3 to match the impedance, then it goes for two different frequency filters, both with the same functionality, but with different frequency setups.

In the Filter 1, the audio passes through HP1 that is a High Pass Filter, cutting 12 Db/oct at 1061 Hz. Right after the low frequency cut, the original signal is smoothly added by the 22K resistor. So the audio goes to LP1, which is a Low pass filter, cutting 12 Db/oct at 1592 Hz, removing this way the frequencies above this threshold, that simulates the Hi tone sound, yet on the human's mid listening zone.

The process repeats with the filter 2, only the frequency setup is different, cutting at 321 and 1026 Hz, this way the Lo tone is created.

After the filters 1 and 2, the audio goes to the item 2 (10KVR-C) that allows the user to choose between Lo and Hi tones, so we have the “Tone” potentiometer.

After the “Tone”

potentiometer, the audio goes through the Block 4 to match the gain and impedance. After this step, the audio is sent to item 3 (10KVR-D—Age), that also is connected to item 1, so the audio signal from Oldalizer meets the clean audio, allowing the user to mix between “Old” and “New” sound character.

At the end, after the “Age” potentiometer (10KVR-D), the audio goes to block 5, that is a simple buffer to match the impedance.

### Instrument Input Selector:

A new version of the “Instrument Input Selector” already shown will be described here. The new version was created from the safety necessity shown by the research with all possible users. This new version avoids the user, or even a non-qualified person to select a wrong kind of instrument pick-up, which can result in dangerous events, such burned loudspeaker.

The present equipment introduces this feature in order to allow the user to have total flexibility with the Instrument input channels of the project. With this feature, musical instruments of any kind can be freely connected to any input channel. There are three different kinds of pick-ups: “Actives”; are those that have built in pre-amplifier, low output impedance and high gain; “Passives”: are those that doesn't have pre-amplifier, so the signal from the pick-up element is sent directly to the amplifier. They are high impedance output and low gain; and Microphone: Are all kinds of instruments, which have its sound captured using a microphone.

### Interface:

There are three leds connected to the microcontroller. Led 0, Led 1 and Led 2. They represent the Active, Passive and Microphone instrument pick-ups respectively.

To select between the three kinds of instrument pick-ups, there's only one select button, which is a tact push button.

To connect the instrument to the channel in question, there's only one input (J-10), which is compatible with the three existent kinds of instrument pick-ups.

### Selection Procedure:

When the equipment is powered, the “Active” pick-up kind is selected by default, represented by Led 0. This way, dangerous mistakes are avoided, as the Active selection is the lowest gain mode.

As soon as the selection

button is pushed, the channel will be muted (to avoid selection noises), and the Led that was on will start to blink. This way, the user will understand that the input selection is in progress, and not applied in fact.

When pressed again (second time) the blinking led is powered off, so the second led replaces and starts to blink.

### When Powered:

### Led 0 on, Led 1 and Led 2 off.

First time that the selector button is pushed:

Led 0 blinking, Led 1 and Led 2 off.

Second time that the selector button is pushed:

Led 0 off, Led 1 blinking and Led 2 off.

Third time that the selector button is pushed:

Led 0 and Led 1 off, Led 2 blinking.

Fourth time that the selector button is pushed:

Led 0 blinking, Led 1 and Led 2 off.

During this process, while the leds are blinking the channel will be absolutely muted, in order to avoid mistakes that would cause loud noises. When finally the user is sure of which is the right kind of instrument pick-up to be selected, he must hold the button for 2 seconds, so the current blinking led will be continuously On, and the channel will leave the mute mode.

### Operation:

Active, Passive and Microphone pick-up instruments needs different gains to be properly amplified, and a compatible input impedance:
Active: Low Gain and Low, Mid or Hi impedance.
Passives: Medium Gain, Medium till Hi impedance.
Microphone: High Gain, Medium till Hi impedance.

As can be seen, all three kinds are compatible with High impedance, that's why the pre-amplifier have High input impedance.

Although all three kinds have a compatible input impedance in common, the same doesn't happen with the gain, so it must be changed according to the kind of instrument connected. In order to change the gain, the resistors R1, R2 and R3 and the two transistors shown are used.

R1 is the operational amplifier's negative feedback resistor, R2 and R3 are connected to its transistors that when triggered, connects the resistor to the ground, attenuating the signal provided by R1.

When the signal provided by R1 isn't attenuated, the op-amp gain is 1, low, compatible with the Active kind of instrument pick-ups.

The R1 attenuation factor is the multiplying factor of the op-amp. As higher is the attenuation, the higher is the gain. So we have R1 and R2 change the gain of the op-amp.

R2 attenuates R1 enough in order to make the pre-amp compatible with Passive instrument pick-ups.

R3 attenuates R1 enough in order to make the pre-amp compatible with Microphone instrument pick-ups.

R2 and R3 will only attenuate

R1 if the transistor connected to them is triggered, which is the microcontroller task.
Transistor of R2 and Transistor of R3 OFF=Active Instruments (Low Gain)
Transistor of R2 ON and Transistor of R3 OFF=Passive Instruments (Medium Gain)
Transistor of R2 OFF and Transistor of R3 ON=Microphone Pick-Up instruments (High Gain).

During the selection process, while the Leds are blinking and are changed, many dangerous and unpleasant noises are created. Furthermore, while the user don't decide definitively which is the instrument pick-up to be connected, is better not to have sound reproduction, in order to avoid mistakes that can cause noises created by audio feedback. This way, during the selection process, the channel is muted till the user finish holding the selection push button, indicating that the kind of pick-up is already selected, so the microcontroller triggers the right transistor to change the gain in accordance to the connected pick-up, and releases the channel from the mute mode, to have the right instrument reproduction.

### Mp3 Player/Recorder:

As the USB Mass Storage devices became very popular, like Pen-Drives and iPods, the expected Audio CD Player was replaced by one Mp3 Player/Recorder, allowing the user to record his live show.

The equipment shown here will be capable of reading mp3, Wave and other audio files through any USB Mass Storage device.

The great new advantage, which differs the equipment from any competitor, is the fact of being the first to have this feature, being capable of record the presentations as audio files on the connected device. This allow the user to record his presentation for many purposes, as personal reference, spread his work, sell the CD right after the show, with inexpensive costs etc.

In order to do this, a new button was added to the Front Panel (Record), and an USB-Host Interface replaced the CD-Tray.

At any moment during the equipment operation, the user can push “Record” button and then all the equipment's audio, even a possible other equipment connected to it through the “Audio Link” is recorded as Audio File.

### EXAMPLE

### REC: 00 h:05 m:35 s

### MicX-InstXY-TubeXY

As the replaced Audio CD-Player, the Mp3 Player/Recorder still compatible with Audio Link and Pre Program Mode features.

1. AUDIO EQUIPMENT, characterized by the fact of include many functionalities that covers a) intuitive user interface for easy equipment handle; b) features Link, P.A. Control, Instrument Input Selector; c) Sound treatment functionalities and integrated effects; d) Integration capability with conventional pro-audio equipments to increase the flexibility, which the user interface includes the front and back panels; the equipment in question includes regarding the input channels, three inputs for microphones with non-balanced J-10 connection and balanced XLR each that allow both kinds to be connected at the same channel; the equipment also includes six instrument input channels with non-balanced J-IO connection, compatible with Active, Passive and Microphone instrument Pick-ups, plus the Bass-Instrument input channel, where the selection is given through a 3-position switch on the back panel with indicative leds for each option chosen; the input channels of the present equipment also includes an Auxiliary Stereo input channel with volume control, to connect any kind of equipments; other feature expected in the equipment is an Audio CD-Player, which is integrated and reproduces any Audio CD that can be executed manually or though a established pre-program mode; the Audio CD Player works together with Audio Link, P.A. Control and have independent volume control; the present equipment have the Audio Link that makes the user interface between two samples of the equipment with microcontroller management; the Audio Link doubles all the features of the equipment, making it work like one integrated equipment since the moment that the samples are connected.

2. AUDIO EQUIPMENT, according to claim 1, characterized by the fact of having the Preprogram mode for the whole musical sequence and intervals of a presentation, avoiding unnecessary artist movement in order to configure the equipment in the desired way for each song and/or interval; the Pre-Program mode memorizes before chosen attributes for each Microphone and Instrument input channels plus the CD-Player, then executes the sequence by receiving a command from the remote control for each step;

3. AUDIO EQUIPMENT, according to claim 1, characterized by the fact of having Audio Effects divided in two groups, being a) the Individuals and b) the Shared; the Individuals are those audio functions that are present as individual modules for each channel, allowing particular adjustments for each input channel without any dependence; while the Shared are those that are present as unitary modules, being connected to the channels chosen by the user, which leads the adjustment made in the effect to be shown in all channels connected to it.

4. AUDIO EQUIPMENT, according to claim 3, characterized by the fact of that inside the Independent group, are expected the independents for microphone, including the Compressor, that compress the voice, which makes it normalize (with level adjustment); Echo, that repeats the obtained sounds (with mix and repeats controls); HPF—High Pass Filter Cleaner, that filters out the very low and subsonic frequencies, which optimizes the compressor response and cleans the sound; and Mic Verb On/Off switch, that connects or not the respective microphone channel to the Shared Mic Verb effect module; Inside the Shared group, for microphone is expected the Mic Verb, which creates artificial reverberation environments and flanger, such Mic Hall 1, Mic Hall 2, Mic Plate, Mic Room, Mic Flanger, where the selection control between the effects is given through the switches Previous and Next, also it has mix control.

5. AUDIO EQUIPMENT, according to claim 3, characterized by the fact of the present equipment also features other kinds of effects, including the independents for instruments, which includes the HPF—High Pass Filter that filters the undesired low frequencies and also optimizes de Compressor response (with level adjustment); Compressor that compress the Instrument's sound, which makes it normalize.

6. AUDIO EQUIPMENT, according to claim 3, characterized by the fact that yet inside the instrument effects group, there are the Shared Effects Modules, which includes the Overdrive, that distort the sound through an electronic tube buffer (with level adjustment); Oldalizer, that is a Vintage Sound Simulator, which works using specific frequency filters together with Tube distortion, in order to re-create the sound of vintage amplifiers (with Tone, Distortion and Age controls); OverVerb, that distort the sound through a Tube buffer (with level control) plus the Tube Verb effect; OldVerb, that is a vintage tone simulator, plus the TubeVerb effect; InstrumentVerb, that create many effects such Reverbs, Delays, Echo, Chorus, Auto-Wah and Rotary Speaker, TubeVerb, that is exactly the same as InstrumentVerb, but it is dedicated to the Tube effects only; the effects InstrumentVerb and TubeVerb have the following variables: Hall 1, Hall 2, Room 1, Room 2, Room 3, Plate 1, Plate 2, Plate 3, Delay 1, Echo, Chorus, Chorus-Room, Auto-Wah, Flanger, Rotary Speaker.

7. AUDIO EQUIPMENT, according to claim 1, characterized by the fact that the proposed equipment also have output channels, being three Stereo Head-Phones output of any impedance and power; two stereo auxiliary outputs channels, one non-balanced RCA and a balanced XLR, in order to interface with any equipments; the present equipment also expects a integrated mono transducer that reproduces with hi performance and fidelity the results obtained through the equipment's hardware, composed by professional and Hi-Fi drivers, bi-amplified with internal frequency crossover, yet expected in the same kind of channels the P.A. Control.

8. AUDIO EQUIPMENT, according to claim 1, characterized by the fact that the effect Oldalizer re-creates the ^{λΛ}vintage sound character from the old amplifiers, this effect features three adjustments: Tone that adjusts from the low to high sound character; Distortion, that mixes the clean with the Tube distorted signal; and Age, that mixes the signal without effect with the signal passed through the Oldalizer, which proportionally, as much less Oldalizer, more new is the obtained sound, as much more Oldalizer, more old is the obtained sound as well; the Oldalizer works from a low impedance audio source, buffer 1, the audio goes forward to two different frequency filters, indicated as F1 and F2, both working the same way, but with different frequency setups; in the Filter F1, the audio pass through HP1 that is a High Pass Filter, cutting 12 Db/oct in 1061 Hz, after that, the original signal is smoothly added by the resistor 22K, and then the audio goes to LP1, that is a Low Pass Filter cutting 12 Db/oct in 1592 Hz, where this filtering process simulates the vintage Hi timber, still in the mid human audible region; the process repeats with F2, but with different frequency setups for the filters, 321 hz and 1026 Hz, creating this way the Lo sound character, and a sound attenuation is provided by resistors Ik and IkI, as it was necessary in the implementation; after the filters F1 and F2, the sound goes to a simple audio buffer to match the impedance in order to correctly drive the potentiometer; after the filters 1 and 2, the audio goes to the item 2, in order to provide to the user, ability to choose between Low and Hi sound character, this way we have the potentiometer Tone Lo/Hi, indicated by the numerical reference; after the Tone potentiometer, the audio goes to another buffer indicated by the numerical reference 3, to match gain and impedance, where after this step, the audio goes to two different ways, clean and distorted patch; to distort the sound, a 12AX7 electronic tube was used, under-supplied with a 5M6 resistor, this way the sound is distorted, as the tube can't amplify the sound in the stipulated gain, creating a normalized and smooth distortion; the tube buffer inverts the signal phase and it's incapable to drive something with low impedance like the potentiometer ahead, so this signal coming from the tube pass through the inverted buffer 4, in order to correct the phase and match the impedance; after the distortion step, the audio enters the potentiometer Distortion indicated by the numerical reference 5, located between the clean and distorted signal patches, it allows the user to mix the signals from clean to totally distorted; after the potentiometer Distortion 5, the audio passes through another buffer 6 to match the impedance, in order to go directly to the Age potentiometer, which is indicated by the numerical reference 7, that also receives the signal without effect; the Age potentiometer 7, is the component that mixes the Oldalizer effect amount.

9. AUDIO EQUIPMENT, characterized by the fact that the equipment in question allows total flexibility regarding the instruments connection, as it is compatible with any kind of pick-ups, being possible to connect it to any of the available instrument input channels.

10. AUDIO EQUIPMENT, according to claim 9, characterized by the instrument (input selector works with the signal coming from a connected instrument, connecting it to its adequate pre-amplifier through the manual switch (1), in such a way that the input impedances are changed according to selected preamplifier.

11. AUDIO EQUIPMENT, characterized by the fact that the present equipment expects yet a P.A. Control system, which through the use of 3-pin J-10 connectors, each output can be connected to equipments with balanced or non balanced input; the system in question have: Master P.A. Volume, which controls the amplitude of all outputs; Bass—Equalizer, bass equalizer for the P.A.; Treble—Equalizer, treble equalizer for the P. A.; Stereo P.A. Output, through two JlO connectors, with independent volume control for each Stereo channel side Left-L and Right-R; Mono P.A. Output, through a JlO connector, with volume control; Stereo Stage Monitor Output, through two JlO connectors with independent volume control for each side Left-L and Right-R, with a two positions selector switch for Mono/Stereo Modes; the whole audio sum of the present equipment (Stereo, L-R) passes through a two-band equalizer with Bass and Treble controls, where the equalizer uses dual potentiometers, in order to equalize both channels (L and R) at the same time; after the equalizer, the audio signal passes through the potentiometer Master P.A. Volume (1), that will control the audio amplitude of every block ahead; after this potentiometer, the signal passes again through audio buffers to match the impedance and correct the phase; after this step, the audio passes through three different ways, being: a) P.A. Mono output; b) P.A. Stereo output; and c) output for Stereo/Mono Stage Monitor; as for the first way the stereo signal becomes mono by joining both channel sides with 5k6 resistors; after that it passes through an audio buffer (3), to match the impedance with the next potentiometer P.A. Mono VoI ahead, which will control the signal amplitude in the mono output, then the audio goes to the output-conditioning block; for the second way, each side of the Stereo channel goes to an independent potentiometer, P.A. —R VoI and P.A. —L VoI, items indicated by the numerical references 8 and 9, offering the user, the ability to control the Left and Right P.A. volume sides separately, then the audio goes to the output-conditioning block; for the third way, we have a manual two-position double switch (4), which for the two contacts of one side, the Stereo channels arrive; for the two contacts of the other side, the mono channel arrives, making it possible to select between Stereo and Mono channels, both as low impedance source to drive the potentiometer correctly; after this selector switch MO/ST (4), there are two potentiometers Stage Monitor VoI-L and Stage Monitor VoI-R indicated by the images 6 and 7, to control the audio amplitude for each channel side, then the audio goes to the output-conditioning block; the output conditioning block receives the audio signal through a non-inverted buffer (10) (phase +), that goes to the tip pin of the J-IO connector (12) through the decoupling resistor 220R, yet in this buffer's output, there's another inverted buffer (11) (phase −), that goes to the middle pin of the J-IO connector, through another 220R resistor, this way, we have a completely balanced output, if we use 3-pins P-IO connector, as the positive (+) and negative (−) signal phases are present, plus the ground, if we use 2-pins P-IO connector, the negative (−) phase is grounded through the 220R resistor and only the positive (+). phase goes to the pin together with the ground, generating this way, an usual non-balanced output.

12. AUDIO EQUIPMENT, developed to give the user the ability to listen to one or more desired instruments/microphones in the stage monitor in dynamic way, according with the claimed in 1, characterized by showing eight options for programmable stage monitor usage, which: 1) 1° Microphones (all, with or without MicVerb); 2) 2° Instrument Channel 1; 3) 3° Instrument Channel 2; 4) 4° Instrument Channel 3; 5) 5° Instrument Channel 4; 6) 6° Instrument Channel 5; 7) 7° Instrument Channel 6; 8) 8° Bass Instrument Channel; the selection works through the microcontroller, using tact push buttons and Display for interactive user interface.

13. AUDIO EQUIPMENT, as claimed in 12, characterized by showing a programmable stage monitors switching, working through microcontroller, display and tact push buttons; the microcontroller have two Wizards in its internal software, the wizard of programmable stage monitors and the pre program mode wizard; both Wizards share the Mp3—Player buttons, which change the function when activated in the described way: STOP=Button PGM; PLAY/PAUSE=Button OK; Previous Track=Back; Next Track=Next; REPEAT=Change button; EJECT=Delete button; the wizard activation is given by holding the PGM button about two seconds, then the Wizard Selector is opened, which the user can choose between programmable stage monitors and pre program mode wizards through a cursor on the display; As the programmable stage monitors wizard is selected, the user chooses between monitor 1 and 2 using the Back and Next buttons and then pushing OK; after this step, the selected monitor appears on the second display line, and bars are accumulated on the first display line according to the chosen options to be reproduced in the selected monitor, which the maximum options allowed are eight, being: MICS; INST 1; INST 2; INST 3; INST 4; INST 5; INST 6 and BASS; after programming the selected monitor, pushing PGM will end the wizard with the settings saved; to program the monitor two or open the pre program mode wizard, the user must hold back about 2 seconds and the wizard will go back to the screen shown before—monitor selector, wizard selector.

14. AUDIO EQUIPMENT, according to claim 1, characterized by the fact of having an output terminal that uses a DB37 connector to put out all in balanced form all the equipments internal channels, which can be connected to equipments that the input is balanced or non-balanced; it also counts with a digital output interface, in order to be compatible with modern digital mixers; through these, all internal channels of the equipment in question can be accessed from external equipments, these channels are: microphones, instruments, bass-instrument, Oldalizer, overdrive, OverVerb, InstrumentVerb, TubeVerb and MicVerb.

15. AUDIO EQUIPMENT, according to claim 8, characterized by the fact of have the Oldalizer with 3 adjustments: Tone: Adjusts between the Lo and Hi sound character; QTD Dist: Adjusts the Tube buffer to obtain the desired distortion; Age: Mix the clean with the signal from Oldalizer; having a Tube step and two internal frequency filters (Low and High sound character), the Oldalizer creates again with fidelity the vintage sound characteristics from a variety of old amplifiers); the audio provided by a low impedance source (buffer, item 1) goes to the first system block that is the distortion, which 10KVR-A (QTD Dist) potentiometer, the audio goes through the Block 4 to match the gain and impedance, wherein after this step, the audio is sent to item 3 (10KVR-D—Age), that also is connected to item 1, so the audio signal from Oldalizer meets the clean audio, allowing the user to mix between Old and New sound character; at the end, after the Age potentiometer (10KVR-D), the audio goes to block 5, that is a simple buffer to match the impedance.

16. AUDIO EQUIPMENT, according to claim 12, characterized by the fact of having a selection for the three existent kinds of instrument pick-ups: Actives: Have built in pre-amplifier, low output impedance and high gain; Passives, send the signal from the pick-up element direct to the amplifier, low gain and high output impedance; Microphone, are all the instruments that uses a microphone as pick-up element.

17. AUDIO EQUIPMENT, according to claim 12, characterized by the fact of having an user interface, which has three leds, Led 0, Led 1 and Led 2 that represents the Active, Passive and Microphone instruments pick-ups respectively; only one selection push button being a tact switch, a J-10 non balanced input which is compatible with all three available kinds through the developed selection system.

18. AUDIO EQUIPMENT, according to claim 9, characterized by selection procedure is given through the following way: when the equipment is powered on the active pick-up kind is selected by default, shown by the Led 0; when the selection button is pushed for the first time, the instrument channel will be muted and the led that was on will start to blink; when pushed the second time, the blinking led is turned off and the next led starts to blink as the last was blinking, and so on; during this selection processes while the leds are blinking, the channel is absolutely muted, so, as soon as the user is sure of which kind of instrument pick-up must be selected, the selection button must be held about 2 seconds, so the current blinking led that represents the kind of pick-up to be selected is turned constantly on and the channel leaves the mute mode.

19. AUDIO EQUIPMENT, according to claim 1, characterized by the fact that the present equipment expects a Mp3 Player/Recorder that at any moment during the equipments operation, the user can push Record button and then all audio sum, even of another equipment sample in Audio Link mode is recorded and will be stored as compressed or uncompressed audio file.

20. AUDIO EQUIPMENT, according to claim 1, characterized by the fact that the present equipment expects an Audio Link system, that uses a microcontroller for smart managing, in the interface of two identical equipment samples, wherein the Link joins the audio channels of both equipments over the link mode.
